(19) United States
(12) Patent Application Publication
(10) Pub. No.: US 2022/0077022 A1
(43) Pub. Date: Mar. 10, 2022

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Tatsuo TONEDACHI, Yamato Kanagawa (JP)

(21) Appl. No.: 17/528,053

(22) Filed: Nov. 16, 2021

Related U.S. Application Data
(63) Continuation of application No. 15/910,429, filed on Mar. 2, 2018.

(30) Foreign Application Priority Data
Sep. 14, 2017 (JP) 2017-176262

(51) Int. Cl. H01L 23/367; H01L 23/00; H01L 23/498; H01L 23/31; H01L 23/043; H01L 25/07; H01L 23/373

(52) U.S. Cl. CPC H01L 23/367; H01L 24/73; H01L 23/49894; H01L 23/3157; H01L 24/32; H01L 23/043; H01L 25/072; H01L 23/3735; H01L 2224/3213; H01L 2224/45124; H01L 2924/1203; H01L 2924/13055; H01L 23/49861; H01L 2224/29101; H01L 24/29; H01L 2224/73265; H01L 2924/3511; H01L 2224/48227; H01L 24/45; H01L 2224/48472; H01L 2224/32225; H01L 2224/48091; H01L 2924/13091; H01L 2924/19107; H01L 24/49

(57) ABSTRACT

A semiconductor device includes a circuit substrate having a first metal layer on a first side, a second metal later on a second side, and an insulating layer between the first and second metal layers. A semiconductor chip is on the first side of the circuit substrate. A metal plate is on the second side. A solder layer is between the metal plate and the second metal layer. The second metal layer includes a protruding region which extends to a first thickness towards the metal plate, a first recessed region, and a second recessed region, each adjacent to the protruding region. The first recessed region extends to a second thickness that is less than the first thickness, and the second recessed region extends to a third thickness that is less than the first thickness.

### CROSS REFERENCE TO RELATED APPLICATIONS

This application is a continuation of U.S. patent application Ser. No. 15/910,429, filed on Mar. 2, 2018, which is based upon and claims the benefit of priority from Japanese Patent Application No. 2017-176262, filed on Sep. 14, 2017, the entire contents of each of which are incorporated herein by reference.

### FIELD

Embodiments described herein relate generally to a semiconductor device.

### BACKGROUND

In a power semiconductor module, there is a plurality of power semiconductor chips mounted on a metal base plate with an insulating substrate interposed between the plurality of power semiconductor chips and the metal base plate. Each power semiconductor chip includes an IGBT (Insulated Gate Bipolar Transistor), a MOSFET (Metal Oxide Field Effect Transistor), or a diode, for example.

The plurality of power semiconductor chips can pass a high current at a high voltage. A low heat dissipation in the power semiconductor module can lead to a reliability failure, such as an open fault, because the plurality of power semiconductor chips generates substantial heat. It is desirable that the heat dissipation of the power semiconductor module be improved.

### BRIEF DESCRIPTION OF THE DRAWINGS

FIG. 1 is a schematic cross-sectional view of a semiconductor device according to an embodiment.

FIG. 2 is an enlarged schematic cross-sectional view of a portion of the semiconductor device according to the embodiment.

FIG. 3 is a schematic cross-sectional view of a semiconductor device according to a comparative example.

FIG. 4 illustrates a problem in a semiconductor device according to the comparative example.

FIG. 5 is a view for explaining aspects of a semiconductor device according to the embodiment.

### DETAILED DESCRIPTION

In this disclosure, corresponding elements are given the same reference signs, and duplicate description thereof may be omitted.

In this disclosure, in order to represent positional relations of components and the like, as the terms an “upper side” and a “lower side” may be used in some contexts. In general, these terms refer to the page orientation(s) depicted in the drawings. However, in this disclosure, the terms “upper side” and “lower side” are not necessarily terms representing relations with the direction of a gravitational force.

In an embodiment, a semiconductor device includes: a circuit substrate having a first metal layer on a first surface side, a second metal later on a second surface side, and an insulating layer between the first and second metal layers; a semiconductor chip on the first surface side of the circuit substrate; a metal plate on the second surface side of the circuit substrate; and a solder layer between the metal plate and the second metal layer. The second metal layer includes a first protruding region which extends from the insulating layer for a first thickness distance towards the metal plate, a first recessed region adjacent to the first protruding region, and a second recessed region adjacent to the first protruding region. The first protruding region is between the first and second recessed regions. The first recessed region extends from the insulating layer for a second thickness distance that is less than the first thickness distance. The second recessed region extends from the insulating layer for a third thickness distance that is less than the first thickness distance.

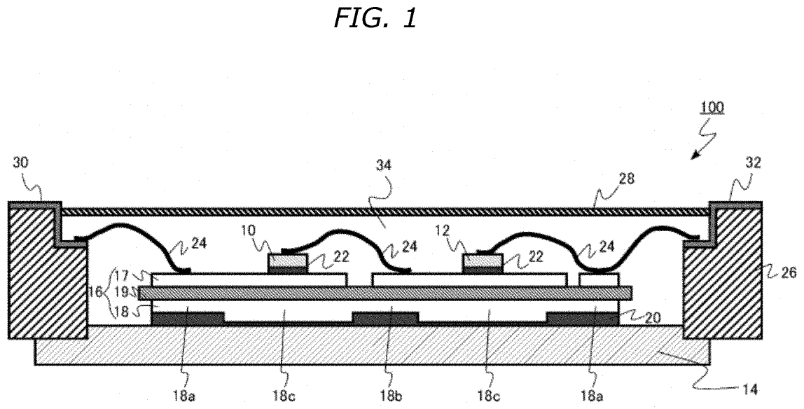

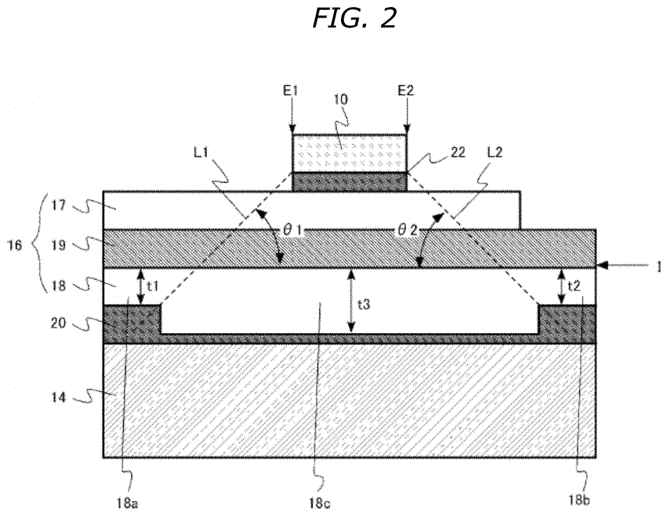

FIG. 1 shows a schematic cross-sectional view of a semiconductor device. FIG. 2 is an enlarged schematic cross-sectional view of a portion of the semiconductor device. The semiconductor device may include a power semiconductor module.

As depicted, a power semiconductor module 100 may include MOSFET 10, MOSFET 12, a metal base plate 14, an insulating circuit substrate 16, a first solder layer 20, a second solder layer 22, a bonding wire 24, a resin case 26, a lid 28, a first electric power terminal 30, a second electric power terminal 32, and silicone gel 34. The insulating circuit substrate 16 may include a first metal layer 17, a second metal layer 18, and a ceramic layer 19. The second metal layer 18 may include a first concave region 18a, a second concave region 18b, and a convex region 18c.

MOSFET 10 and MOSFET 12 are provided on the insulating circuit substrate 16. MOSFET 10 and MOSFET 12 may include a power MOSFET with a high withstand voltage or a vertical type MOSFET using silicon or silicon carbonate, for example. MOSFET 10 and MOSFET 12 may be fixed to the first metal layer 17 by the second solder layer 22.

MOSFET 10 and MOSFET 12 may be fixed to the first metal layer 17 using a silver paste instead of the solder by sintering bonding method. The MOSFET 10 or MOSFET 12 may be provided as a semiconductor chip.

The metal base plate 14 may be formed of copper, for example, pure copper or copper alloy, or may be formed of aluminum.

A heat dissipation plate not specifically depicted in the figure may be provided on a backside surface of the metal base plate 14 when the power semiconductor module 100 is mounted in a final product. A power semiconductor module 100 and the heat dissipation plate can both be fixed to the metal base plate 14. Thermal grease may be interposed between the metal base plate 14 and the heat dissipation plate, for example.

The metal base plate 14 has a surface (on the side facing the insulating circuit substrate 16) has a convex shape, that is, the metal base plate 14 has a shape in which a center portion of the reverse surface protrudes relative to an edge portion of the reverse surface.

The insulating circuit substrate 16 is provided between MOSFET 10 and the metal base plate 14 and between MOSFET 12 and the metal base plate 14. The insulating circuit substrate 16 is provides electrical insulation between MOSFET 10 and the metal base plate 14 and between MOSFET 12 and the metal base plate 14. The first solder layer 20 is provided between the metal base plate 14 and the insulating circuit substrate 16.

The insulating circuit substrate 16 may include the first metal layer 17, a second metal layer 18, and a ceramic layer 19. The first metal layer 17 and a second metal layer 18 may be copper, for example. The ceramic layer 19 may comprise aluminum oxide, silicon nitride, or aluminum nitride. The ceramic layer 19 is an electrically insulating film.

The second metal layer 18 includes a first concave region 18a, a second concave region 18b, and a convex region 18c (also referred to as a third region). The convex region 18c is between the first concave region 18a and a second concave region 18b.

The first concave region 18a has a first thickness (referred to as t1 in FIG. 2). The second concave region 18b has a second thickness (referred to as t2 in FIG. 2). The convex region 18c has a third thickness (referred to as t3 in FIG. 2). The third thickness t3 is thicker than the first thickness t1 and the second thickness t2. The first thickness t1 and the second thickness t2 are set to be between 0.4 to 0.9 of the third thickness t3, inclusive.

The first thickness t1, the second thickness t2, and the third thickness t3 can be compared using microscope image of device cross-sections.

The first thickness t1 and a second thickness t2 may be set from 0.16 mm to 0.76 mm. The third thickness t3 may be set from 0.4 mm to 0.8 mm.

The convex region 18c is disposed between MOSFET 10 and the metal base plate 14 and between MOSFET 12 and the metal base plate 14. The convex region 18c is arranged directly below MOSFET 10 and MOSFET 12.

An angle (referred to as θ1 in FIG. 2) between a first line segment (referred to as L1 in FIG. 2) connecting between a first end of MOSFET 10 (referred to as E1 in FIG. 2) and a boundary edge portion between the first concave region 18a and the convex region 18c and an interface (referred to as I in FIG. 2) between the second metal layer 18 and the ceramic layer 19 is 45 degrees or less. Also, an angle (referred to as θ2 in FIG. 2) between a second line segment (referred to as L2 in FIG. 2) virtually connecting between a second end of MOSFET 10 (referred to as E2 in FIG. 2) and a boundary edge portion between the second concave region 18b and the convex region 18c and the interface (referred to as I in FIG. 2) between the second metal layer 18 and the ceramic layer 19 is 45 degrees or less.

The first concave region 18a, the second concave region 18b, and the convex region 18c can be formed by etching metal of a flat plate shape, for example.

The first solder layer 20 may be provided between the second metal layer 18 and the metal base plate 14 to fix the insulating circuit substrate 16 to the metal base layer 14. A major component of the first solder layer 20 may include an alloy of tin (Sn)—lead (Pb), an alloy of tin (Sn)—silver (Ag), an alloy of tin (Sn)—bismuth (Bi), an alloy of tin (Sn)—cupper (Cu), an alloy of tin (Sn)—indium (In), or an alloy of tin (Sn)—antimony (Sb) including antimony (Sb), for example.

The resin case 26 is a frame body provided surrounding a periphery of the insulating circuit substrate 16. The lid 28 formed of resin may be provided on the resin case 26 and may enclose the insulating circuit substrate 16 between the metal base plate 14.

A silicone gel 34 may be used as a sealant inside of the power semiconductor module 100. The resin case 26, the metal base plate 14, the lid 28, and the silicone gel 34 can protect and insulate the materials of the inside of the power semiconductor module 100.

On an upper portion of the resin case 26 may be provided the first electric power terminal 30, the second power electric terminal 32, and an AC output terminal (not shown), and a gate terminal (not shown). The first electric power terminal 30 and the second electric terminal 32 electrically connect the power semiconductor module 100 to the outside.

The first electric power terminal 30 may be electrically connected to the first metal layer 17 using a bonding wire 24. Each of MOSFET 10 and MOSFET 12 may be electrically connected to the first metal layer 17. The first metal layer 17 may be electrically connected to the second power electric terminal 32 using a bonding wire 24. The bonding wire 24 may include aluminum wire, for example.

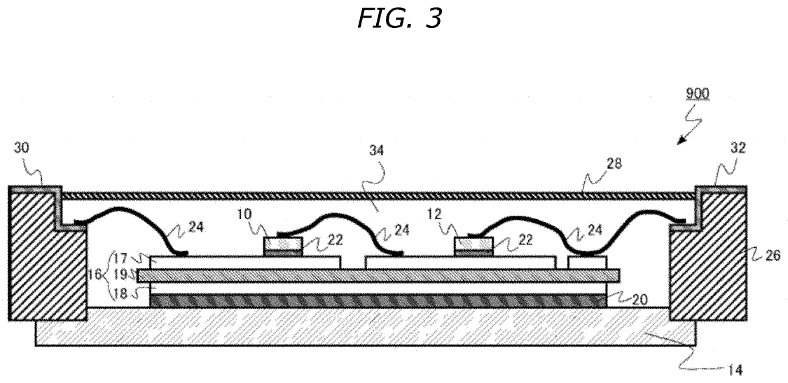

FIG. 3 is a schematic cross-sectional view of a semiconductor device according to a comparative example.

The power semiconductor module 900 according to the comparative example is different from the power semiconductor module 100 in that a convex region 18c is not provided on the second metal layer 18 of the insulating circuit substrate 16, that is, the second metal layer 18 in the power semiconductor module 900 has a flat plate-like shape.

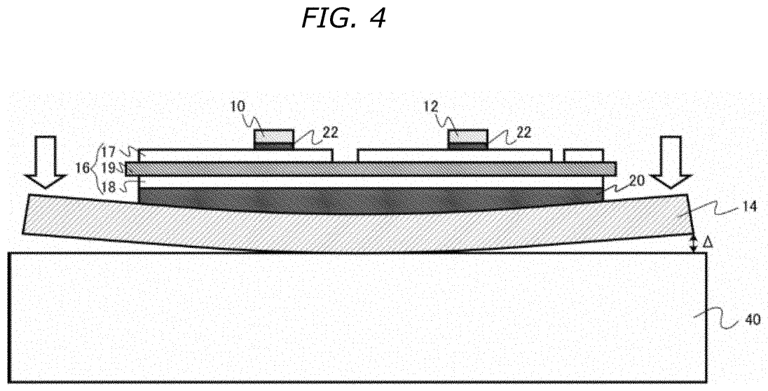

FIG. 4 is a view of the semiconductor device according to the comparative example. FIG. 4 depicts a portion of the power semiconductor module 900 and a heat dissipation plate 40.

The heat dissipation plate 40 is connected to the metal base plate 14 when the power semiconductor module 900 is mounted in a final product. The edges of the power semiconductor module 900 and the heat dissipation plate 40 are fixed to the metal base plate 14 and the heat dissipation plate 40 adhesively. Thermal grease can be interposed between the metal base plate 14 and the heat dissipation plate 40, for example.

The metal base plate 14 has a warped shape so that a central portion thereof protrudes further downwardly relative to an edge portion. Warpage amounts for the metal base layer 14 (referred to as Δ in FIG. 4) is from 0 mm to 1 mm, or no less than 0.1 mm to 1 mm, for example. FIG. 4 exaggerates the warpage amounts for purposes of description.

When the reverse surface of the metal base plate 14 does not have a convex warped shape, there is possibility that a gap forms between the center portion of the base plate 14 and the heat dissipation plate 40. This gap may be filled with thermal grease having a low heat conductivity or may be an air gap having even lower heat conductivity therefore, there is possibility that heat resistance rises and the heat dissipation is decreased.

When t the metal base plate 14 has the warped shape, a thickness of the first solder layer 20 between the center portion of the insulating circuit substrate 16 and the metal base plate 14 becomes relatively large compared with a thickness between the edge portion of the insulating circuit substrate 16 and the metal base plate 14. A heat conductivity of the solder is a considerably lower compared with heat conductivities of the second metal layer 18 and the metal base plate 14. Also, as the solder layer becomes thicker, an occurrence of voids in the solder becomes higher.

Accordingly, it is not desirably that the thickness of the first solder layer 20 becomes thicker, especially, it is not desirably that the thickness of the first solder layer 20 just below MOSFET 10 and MOSFET 12, which each generate a large amount of heat, becomes thicker.

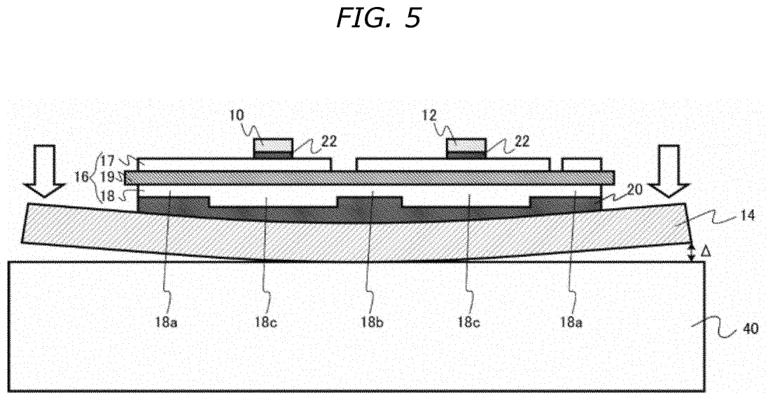

FIG. 5 is a view for explaining an operating and an effect of the semiconductor device according to the present embodiment, and shows a portion of the power semiconductor module 100 and the heat dissipation plate 40.

The convex region 18c is provided in the second metal layer 18 below MOSFET 10 and MOSFET 12, which each generate a large amount of heat, thereby, the thickness of the first solder layer 20 below each of MOSFET 10 and MOSFET 12 can be thinner. Therefore, the heat resistance can be decreased and the heat dissipation can be improved compared to the comparative example.

The convex regions 18c may be referred to as protrusions or protruding portions in that they extend at a greater distance in a direction normal to a lower surface of ceramic layer 19 than adjacent regions (18a and 18b) of the second metal layer. The first concave region 18a and the second concave region 18b may be referred to as recesses or recessed portions in comparison to the protruding aspect of the convex regions 18c.

It is desirable that the first thickness t1 of the first concave region 18a and the second thickness t2 of the second concave region 18b are set from 0.4 to 0.9 times the third thickness t3 of the convex region 18c. When the first thickness t1 and the second thickness t2 are below the above range, processing is generally more difficult. Second, a variation in the solder amount of the first solder layer 20 becomes large in the boundary between the first concave region 18a and the convex region 18c and the boundary between the second concave region 18b and the convex region 18c and this may lead to solder cracking. Third, forming of an alloy of the second layer 18 and the first solder layer 20 is not sufficient to decrease the adhesive property between the insulating circuit substrate 16 and the metal base plate 14. When the first thickness t1 and the second thickness t2 are over the above range, there is possibility that the thickness of the first solder layer 20 becomes thick and this will decrease the heat dissipation.

The angle (referred to as θ1 in FIG. 2) between the first line segment (referred to as L1 in FIG. 2) virtually connecting between the first end of MOSFET 10 (referred to as E1 in FIG. 2) and the boundary portion between the first concave region 18a and the convex region 18c and the interface (referred to as I in FIG. 2) between the second metal layer 18 and the ceramic layer 19 may be set to 45 degrees or less. Also the angle (referred to as θ2 in FIG. 2) between the second line segment (referred to as L2 in FIG. 2) virtually connecting between the second end of MOSFET 10 (referred to as E2 in FIG. 2) and the boundary portion between the second concave region 18b and the convex region 18c and an interface (referred to as I in FIG. 2) between the second metal layer 18 and the ceramic layer 19 may be set to 45 degrees or less.

As the above configuration, a thin region the first solder layer 20 is provided below MOSFET 10 to improve the heat dissipation.

When the major component of the first solder layer 20 includes the alloy of tin (Sn)—antimony (Sb) including antimony (Sb), the power semiconductor module 100 according to the present embodiment can be effectively operated in expected operating ranges. The alloy of tin (Sn)—antimony (Sb) has a high heat resistance, while having comparatively low heat conductivity. Therefore, the power semiconductor module 100 with both a high heat resistance and a high heat dissipation can be achieved.

The semiconductor module 100 according to the present embodiment can have a relatively thin the first solder layer 20 between the insulating circuit substrate 16 just below the semiconductor chip and the metal base plate 14 to improve the heat dissipation of the semiconductor module 100.

A MOSFET is used as the semiconductor chip in the present embodiment, but the other transistors or diodes, for example, IGBT etc. may be used instead or in addition to. Also, a combination of MOSFET and a diode or a combination of IGBT and a diode may be used.

The number of semiconductor chips (e.g., MOSFET 10 and MOSFET 12) mounted on the insulating circuit substrate 16 is not limited two, but rather one chip or three or more chips may be mounted on a single insulating circuit substrate. Also, the semiconductor module 100 may include two or more insulating circuit substrates 16.

The silicone gel 34 is used as the sealant in the present embodiment, but the other resin materials, for example, an epoxy resin may be used as the sealant.

While certain embodiments have been described, these embodiments have been presented by way of example only, and are not intended to limit the scope of the disclosure. Indeed, the methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a circuit substrate having a first metal layer on a first surface side, a second metal layer on a second surface side, and an insulating layer between the first and second metal layers;
a semiconductor chip on the first surface side of the circuit substrate;
a metal plate on the second surface side of the circuit substrate; and
a solder layer between the metal plate and the second metal layer, wherein
the second metal layer includes a first protruding region which extends from the insulating layer for a first thickness distance towards the metal plate, a first recessed region on a first edge and a second recessed region on a second edge on an opposite side to the first edge, the first protruding region being between the first recessed region and the second recessed region, the second metal layer having a non-zero thickness in the first recessed region and the second recessed region,
the first recessed region extends from the insulating layer for a second thickness distance that is less than the first thickness distance,
the second recessed region extends from the insulating layer for a third thickness distance that is less than the first thickness distance,
the metal plate is warped by a non-zero amount,
a portion of the solder layer proximate to an outer edge of the circuit substrate and contacting the first recessed portion is thinner in a direction normal to the circuit substrate than a portion of the solder layer proximate to central portion of the circuit substrate and contacting the second recessed portion,
the semiconductor chip is disposed on the circuit substrate and the first protruding region is sized and positioned such that:
an angle between a first line segment virtually connecting a third edge of the semiconductor chip on a first end of the semiconductor chip and a boundary between the first protruding region of the second metal layer and the solder layer and an interface between the second metal layer and the insulating layer is 45 degrees or less, and
an angle between a second line segment virtually connecting a fourth edge of the semiconductor chip on a second end of the semiconductor chip and a boundary between the first protruding region of the second metal layer and the solder layer and the interface between the second metal layer and the insulating layer is 45 degrees or less.

2. The semiconductor device according to claim 1, wherein the semiconductor chip is above the first protruding region.

3. The semiconductor device according to claim 2, wherein the semiconductor chip is not above the first and second recessed regions.

4. The semiconductor device according to claim 1, wherein
the second thickness distance is between 40% and 90% to the first thickness distance, and
the third thickness distance is between 40% and 90% to the first thickness distance.

5. The semiconductor device according to claim 4, wherein the second and third thickness distances are equal to each other.

6. A semiconductor device, comprising:
a circuit substrate having a first metal layer on a first surface side, a second metal layer on a second surface side, and an insulating layer between the first and second metal layers;
a semiconductor chip on the first surface side of the circuit substrate;
a metal plate on the second surface side of the circuit substrate; and
a solder layer between the metal plate and the second metal layer, wherein
the second metal layer includes a first protruding region which extends from the insulating layer for a first thickness distance towards the metal plate, a first recessed region, and a second recessed region on a second edge on an opposite side to the first edge, the first protruding region being between the first recessed region and the second recessed region, the second metal layer having a non-zero thickness in the first recessed region and the second recess region,
the first protruding region is between the first and second recessed regions,
the first recessed region extends from the insulating layer for a second thickness distance that is less than the first thickness distance,
the second recessed region extends from the insulating layer for a third thickness distance that is less than the first thickness distance,
the metal plate is curved by a non-zero amount so that a surface on a side facing away from the circuit substrate has a convex shape,
the semiconductor chip is disposed on the circuit substrate and the first protruding region is sized and positioned such that:
an angle between a first line segment virtually connecting a third edge of the semiconductor chip on a first end of the semiconductor chip and a boundary between the first protruding region of the second metal layer and the solder layer and an interface between the second metal layer and the insulating layer is 45 degrees or less, and
an angle between a second line segment virtually connecting a fourth edge of the semiconductor chip on a second end of the semiconductor chip and a boundary between the first protruding region of the second metal layer and the second solder layer and the interface between the second metal layer and the insulating layer is 45 degrees or less.

7. The semiconductor device according to claim 1, further comprising:
an adhesive layer provided between the semiconductor chip and the first metal layer.

8. The semiconductor device according to claim 1, wherein the insulating layer comprises aluminum oxide, silicon nitride, or aluminum nitride.

9. The semiconductor device according to claim 1, wherein the metal plate comprises copper.

10. The semiconductor device according to claim 1, wherein the first metal layer and the second metal layer comprise copper.

11. The semiconductor device according to claim 1, wherein the solder layer comprises antimony.

12. The semiconductor device according to claim 1, further comprising:
a frame body surrounding a periphery of the circuit substrate;
a lid connected to the frame body and disposed on the first surface side of the circuit substrate; and
a sealant between the circuit substrate and the frame body and between the circuit substrate and the lid.

13. The semiconductor device according to claim 6, further comprising:
an adhesive layer provided between the semiconductor chip and the first metal layer.

14. The semiconductor device according to claim 6, further comprising:
a frame body surrounding a periphery of the circuit substrate;
a lid connected to the frame body and disposed on the first surface side of the circuit substrate; and
a sealant between the circuit substrate and the frame body and between the circuit substrate and the lid.

15. The semiconductor device according to claim 6, wherein the semiconductor chip is above the first protruding region.

16. The semiconductor device according to claim 15, wherein the semiconductor chip is not above the first and second recessed regions.

17. The semiconductor device according to claim 1, wherein the second end of the semiconductor chip is on an opposite side to the first end of the semiconductor chip.
